(19) United States
(12) Patent Application Publication
(10) Pub. No.: US 2009/0204352 A1
(43) Pub. Date: Aug. 13, 2009

(54) METHOD FOR PRODUCING MULTIDIMENSIONAL CALIBRATING PATTERNS

(75) Inventors: Konstantin Anatolyevich Zharinov, Sankt-Petersburg (RU); Pavel Aleksandrovich Luzanov, Sankt-Petersburg (RU)

Correspondence Address: WALKER & JOCKE, L.P.A., 231 SOUTH BROADWAY STREET, MEDINA, OH, 44256, US

(73) Assignee: LUMEX INSTRUMENTS LIMITED, Nicosia (CY)

(21) Appl. No.: 12/305,122

(22) PCT Filed: May 31, 2007
(86) PCT No.: PCT/RU2007/000317

§ 371 Date: Dec. 16, 2008

(30) Foreign Application Priority Data
Jun. 20, 2006 (RU) 2006122456

(51) Int. Cl. G01R 35/00

(52) U.S. Cl. 702/85

(57) ABSTRACT

The declared invention relates to analytical instrument making, in particular, to the methods of calibration models formation for measuring instruments of various kinds.

This method includes selection of calibration set samples with known secondary properties using specific reference methods; measurement primary properties of every sample from the calibration set with known secondary properties on the reference instrument and transformation of the measurements of the primary properties of the calibration set samples using correlation of calibration transfer to the form equivalent to the calibrated instrument; development of the calibration model with the help of regression analysis methods using transformed calibration correlation data allowing to determine the analyzed secondary properties of the unknown sample according to the measurements of the plurality of the primary properties of this sample carried out on the calibrated instrument. This method of regression analysis is different because the correlation of calibration transfer is found The problem of the present invention is the formation of a multivariate calibration model, which provides a high accuracy of analyzed properties determination and is stable to the changes of properties, influencing the measurement results of the instrument, and even in case of the similar factors repeated change, in particular, to possible linear and nonlinear instrument's technical parameters differences, arising owing to ageing, performance of repair or replacement of separate typical elements of the design, change of operational conditions, and also other factors, any way, the labor input and the construction procedure duration of the similar model, subsequently applied for the determination of one or several secondary properties of the unknown sample by the results of the multiple primary properties measurement of this sample, and not necessarily spectral ones, decrease.

The solution of the problem put by is achieved with the help the of multivariate calibration models formation method, consisting of a sequence of actions united by a uniform inventor's plan. The method includes the calibration set samples selection with the known secondary properties, determined by reference methods; the instrumental measurement of each calibration set samples' primary properties; the artificial alteration, at least, in one of the properties, affecting the instrument measurement results; measurement of, at least, one sample on the instrument with the primary properties in the state, changed in this way; the formation of a calibration model, stable to the specified changes, by finding through multivariate regressive analysis methods with the use of the data, obtained on the instrument after the introduction of changes, the calibration relationships, allowing one to determine the analyzed secondary properties of the unknown sample by measurement results of the set of primary properties of this sample, which differ by the fact that before the change introduction they form a set of samples for calculation of correcting relationships, they measure the primary properties of each sample from this set on the instrument before and after the alteration, and, comparing by means of multivariate regressive analysis methods the measurement results of the primary properties of samples of the set, obtained on the instrument before alteration, with the measurement results of primary properties of the same samples, obtained on the instrument in the state when changes are made, they determine the correcting relationships; therefore, the correcting relationships, found for one instrument and considering the brought in changes, are used on any other instrument of the given type at a stable to the specified changes calibration model construction; they carry out a transformation of the measurement results of the calibration set samples' primary properties by means of the obtained correcting relationships to the form, corresponding to the measurements on the instrument after alterations, thus, corrected for the changed state of the instrument, they supplement with the primary properties measurement results of the calibration set samples the calibration samples' primary properties measurement results, obtained on the instrument before the alteration, moreover, the check of the multivariate calibration model formed on the population of the initial and corrected primary properties measurement results of the calibration set samples, are made, carrying out a validation procedure and using the quantitative parameters of calibration validation determined on the basis of it.

The declared invention relates to analytical instrument making, in particular, to the methods of calibration models formation for measuring instruments of various kinds.

In many branches of industry and scientific research, the sample properties determination by means of direct methods of measurement does not provide the required analysis speed or leads to the destruction of the sample, and in some cases the direct determination of the required properties in general can appear impossible. As an example, it is possible to apply to analytical chemistry where the traditional direct method of chemical analysis for the determination of concentrations forming the components sample is based on carrying out chemical reactions what leads to the destruction of the sample, and besides it is time consuming.

In similar cases, indirect methods became widespread, where the analyzed properties of samples are determined by measuring other properties of samples, depending on the analyzed ones, which, however, unlike the analyzed properties, can be easily measured directly during a short time interval and without the destruction of the sample. In addition, directly measured properties of samples are often called “primary properties”, and the analyzed properties of samples are “secondary properties”. One of the most effective indirect research methods is the spectroscopic analysis at which the demanded “secondary” properties of samples (for example, their chemical composition) is determined on the basis of the optical spectra of absorption, reflection or dispersion (“primary” properties) measurement.

After the measurement of the primary properties set, it is necessary to determine the mathematical relationship connecting the measurement results with the size values, describing the analyzed secondary properties. These relationships between the primary characteristics measured on the instrument and the analyzed secondary properties of the sample are called calibrating models or calibrations; in the result of their finding, a number of calibrating constants is determined. The procedure of calibration models formation is rather labor consuming, long and expensive. This process becomes especially complicated for the case of the multivariate analysis, when, for the quantitative characteristics of the sample secondary properties determination, a set of measurement results of a big number of parameters describing the primary properties is used. For example, in case of the spectroscopic analysis for the various components concentration determination a big quantity of spectral data (values of absorption, reflection or dispersion) for different values of wave numbers (wavelength, frequencies) is measured.

To make the constructed calibration model provide the prescribed accuracy of parameters determination describing the analyzed secondary properties of any given sample, it is necessary to conduct an analysis of a big number of samples, representative to those samples which will be analyzed on the instrument in future (calibration set). The selection of calibration set samples is regulated by standards for various indirect methods of analysis, for example, the standard for quantitative analysis by means of near infrared spectroscopy [1]. The values of the parameters describing the analyzed secondary properties of the calibration set samples are preliminarily determined by means of standard methods named reference. At carrying out the reference analyses, it is necessary to pay special attention to the accuracy of the analyses results as the reference analysis accuracy limits the accuracy of all calibration. For example, in the case of the spectroscopic analysis of the samples' chemical composition considered earlier, the calibration set analyzed properties can be preliminarily determined by standard chemical methods with the use of chemical reactions.

The calibration set samples are chosen in such way, that their secondary properties would cover a possible range of these properties alterations at the analysis of unknown samples, and would be distributed at regular intervals within this range. The implementation of the given conditions raises the calibration model's stability owing to this fact small noise alterations in the measured primary properties do not lead to the statistically significant changes in the secondary properties analysis results.

The formed calibration model should be exposed to the standard procedure of validation [1], in the result of which the statistical parameters describing the calibration model quality as well as the samples dropping out of calibration is determined. The statistical analysis of outliers is applied to search such samples, for example, by Mahalanobis distance [1], which uses the primary properties measurement data of the full calibration set. For the increase of calibration stability, it is necessary to exclude such samples from the calibration set.

To assess the calibration models applicability for the description of an unknown sample, the measured primary properties of the sample are also exposed to the analysis according to the outlier prediction statistics. This problem is similar to the problems solved at the qualitative analysis, where, on the basis of the sample's primary properties measurement (spectral data) and their comparison with the library data, the conclusion about the set of components in the sample is made. It is necessary to notice, that the analyzed samples measurement conditions and the calibration samples conditions should be identical.

The samples' primary properties measurement results and, as a consequence, the accuracy of determination of the parameters describing the analyzed samples secondary properties, can be essentially affected by various properties, for example, changes of external conditions or measuring instrument characteristics. It is necessary to note, that the instrument characteristics can change in due course owing to ageing or at carrying out repair work, or at replacement of separate typical design elements of the instrument. In that case, the formation of a new calibration model accounting of the instrument current condition features can be required. As it was noted earlier, this process is long, labor consuming and expensive. Therefore several methods of formation of calibration models, stable to alteration of measurement conditions, or instrument characteristics and other properties affecting the results have been offered, they permit not to repeat a complex process of calibration model construction for each separate instrument after its repair, replacement of separate typical design elements or change of instrument parameters with time.

One of similar methods [3] considers the construction of the instruments' calibration model for the chemical composition spectroscopic analysis, which is not sensitive to change of instrument's characteristics. The given approach was applied by T. Scecina, and others, who based on the fact that the artificial addition to the calibration model of the spectra of the samples measured at the change of a concrete affecting parameter (for example, temperature or pressure) over the expected change range in operation improves the analysis with the use similar model of those samples for which change of the given parameter is characteristic. While applying the specified concept in relation to the measuring instrument characteristics change, the algorithm, which allows accounting similar changes, has been developed. The specified method takes account of the spectral instruments variability due to the inclusion into the calibration model of the spectra of the samples registered upon changing of certain instrument parameters to cover the whole possible range of similar changes. This idea is practically identical to the method described in the patent [2]. For example, the wavelength displacement by a certain amount for all points in which measurements are being made is entered, or the amount of this displacement is proportional to the concrete point position on the wave numbers axis. The account of similar changes by means of spectra mathematical processing is also permitted.

On the other hand the opportunity of the considered algorithm modification, consisting in calibration models formation on several instruments is offered, it is preferable that these instruments' characteristics covered the possible range of the specified characteristics change on all instruments of the given series. Then the obtained data are united in a uniform calibration set and are in addition the instrument characteristics changes are artificially entered by means of mathematical manipulations above the spectral data. Such approach allows taking account of the instrument's parameters variability in a greater degree, making the formed model steadier.

However, this method demands a big number of measurements what leads to the increase of work, time and material resources burden at the stage of calibration model formation. The considered algorithm is not deprived of other drawbacks, namely, model accuracy decrease since variation of primary properties measurement results in the model is initially supposed, and the complexity of estimation of the calibration model application legitimacy for the analysis of this or that unknown sample that can lead to mistakes in the secondary properties analysis.

One more method, devoted to the calibration models formation compensating the instrument parameters changes, is offered in [4]. According to this method, spectrometers are characterized by means of their spectra (spectral characteristics) conformity determination to the preliminarily determined limited number of clusters. The belonging to a cluster is determined on the basis of the spectral features and performance data similarity. The spectral features, used for classification, can be attributed to the known instrument's parameters or can represent some abstract characteristic features, obtained by means of computing methods. The calibration model for each cluster compensates the instrumental changes; it will be more simple and exact.

The offered algorithm includes four stages: measurement, classification, calibration, and determination of outlier samples. At the first stage, the measurement of spectra of certain standards, which can be used, for example, for classification of the displacement, observed within the wavelengths axis or by intensity. The kind of measured standards is defined by the effects, which should be considered in each concrete case. Generally, the instrument changes can be classified on the basis of the spectral data into the following kinds: signal intensity, bandwidth, wavelength changes or a combination of the specified phenomena. Their detailed enough classification is given in the considered source. It is necessary to note, that in some cases real samples, modeling measurement features by means of the given instrument, can serve as standards. At the second stage, classifying of the obtained spectra is required. For this purpose characteristic spectral features are allocated with the use of mathematical obtained data transformations, which improve certain aspects, useful for interpretation, for example, principal component analysis, Mahalanobis distance calculation. In addition, the given features can be obtained on the basis of the aprioristic knowledge of the system (noise characteristics, detector's linearity, etc.). Further the classification is executed, that is, attribution of the obtained spectra to certain clusters is made, and the classification model is developed by finding of a law, allowing defining, what cluster the measured sample spectrum corresponds to. At the third stage a calibration model for each cluster is built, this model takes account of instrument changes, characteristic for this cluster. Spectra inside a determined cluster have a high degree of the internal constancy and possess similar features, defining not all possible changes of the instrument parameters, but only one or several, considered inside the cluster. Such approach allows simplifying the procedure of the individual cluster calibration formation. Its other advantage is the option for outlier spectra determination. As each cluster has its own set of classification requirements, if the measured spectrum does not conlply with it, an attempt to pick up another cluster, which parameters allow conducting the specified spectrum analysis, is made. If it appears impossible, the given spectrum is exposed to the mathematical processing in order to make it correspond to one of the clusters. If the compliance is impossible to reach, the spectrum is considered outlier.

Actually, it is a modification of the method, described in the previous patents, with the introduction of changes into the instruments characteristics at calibration model construction. The difference here is that not the whole possible range of changes is considered, but it is split into several sub ranges (clusters), in each of which, for example, only one parameter is measured in the limited range of values. A calibration model is constructed, on the basis of which the secondary properties are determined with high enough accuracy for all instruments, which primary properties are characterized by that cluster. For the instruments from another cluster (another parameter or the same parameter, but in another range of values, is changed) an independent calibration model is constructed or a calibration transfer by known methods is carried out.

The simplicity of the calibration model and a high enough accuracy of the secondary properties determination for a concrete cluster, as well as the opportunity of outlier spectra determination, allows estimating the legitimacy of the calibration model application for this or that unknown sample analysis, and, accordingly, allows lowering the probability of mistakes in the secondary properties analysis can be attributed to the advantages of the given method. The necessity of a great number of operations to perform in connection with the clusters determination, with finding of qualifying algorithms and calibration models construction for each cluster, and also a narrow directivity of the offered method at spectrometer instruments refer to its disadvantages.

There is a method of calibration models transfer between instruments [5], which can be used for calibration of one instrument, to take account of changes in the instrument characteristics, arisen while in service owing to various reasons, in particular ageing. According to the given method, for the account of similar changes a set of samples is chosen, for example, from those that were used at the calibration model formation. Primary properties of each sample from this set are measured with the instrument, which characteristics have changed eventually, and the comparison by means of regressive methods of measurement of the set samples primary properties results with the results of the primary properties measurement of the same samples, obtained on the instrument at the initial condition, for which the calibration was made, is carried out. Thus, the relationships for results transformation of measurements, carried out on the initial instrument, to the form equivalent to measurements on the instrument in its current state, at which there were some changes in characteristics while in service, are determined. Later on by means of the found relationships the data for the samples calibration set, measured on the initial instrument, will be transformed to the form equivalent to the calibration set samples measurement results on the instrument in the current state, and on these transformed data a calibration model is formed.

Formed by means of the given method, the calibration model takes account of the changes, which took place in the instrument characteristics while in service, provides a high enough accuracy of analyzed properties determination, in addition there is no necessity to repeat measurements on the instrument of all calibration set samples, what reduces the duration and labor input of the graduation process. At measurement of an unknown sample, the opportunity of carrying out of the outlier data analysis by means of outliers prediction statistics is admitted, what allows estimating the legitimacy of calibration model application. For the accounting of the interfering factors effect, such as distinctions in sample preparation and in the state of samples, it is offered to use a normalization procedure with the use of various kinds of the measurement results and the data on the secondary properties (referent data) mathematical preprocessing.

The essential drawback of the given invention is that the created calibration model takes account only of the instrument's current state and its characteristics, as well as of other properties influencing measurement results. Thus, with time these properties can change again owing to various reasons, in particular, ageing, performance of repair of the instrument, replacement of separate constructive elements, and change of operational conditions. As a result, the analysis error under the formed calibration model may increase, and finally, there will be a necessity of a new calibration construction, that is, a recurrence of all operations, described above, according to the given method even in the event if there is a repeated change of the same characteristics.

There is another method [2] of formation of multivariate calibration models, which are not sensitive to the parameters change of the instrument, on which the measurements are carried out, as well as to change of external conditions, at which the measurements are carried out, and to change of other properties of the sample. By the population of essential attributes, the given method is the closest to the stated invention, and it is chosen as a prototype. According to the considered method of calibration models formation the required quantity of calibration samples with the known secondary properties are chosen, so that other properties of samples would change in the greatest possible range of expected changes. Then, for each of the chosen calibration samples, a big number of parameters, describing the primary properties of the sample, is measured on the instrument, for which the calibration model is constructed; after that a mathematical processing of the obtained results is carried out, and a number of calibration constants in the relationships between the amounts values, describing the primary and the secondary properties of the calibration samples, is determined. The peculiarity of the method consists in the fact that during the measurements for one or several samples from the calibration set intentional changes are made, at least, in one of the measuring instrument parameters, besides, the external conditions change may be additionally entered. The amount of the specified parameters changes at calibration model construction should be the same order or greater, than the expected amount of these parameters change between various instruments while in service. The instrument parameters or other measurement conditions changes can be also entered not during carrying out of real measurements, but by means of mathematical transformations. For example, in case of spectrometers based on a monochromator it is offered to make measurement of one or several samples used for calibration, having intentionally made a displacement of the wavelength in the range of values, which can be expected at operation. It can be achieved, having made the monochromator physical changes (depending on the design, the displacement or a change of the inclination angle of the grating or the filter, change of the apertures position on the grating may be used, or change of the falling radiation angle of incidence) or by means of change of the constants used for calculation of the monochromator wavelengths.

The analysis results secondary properties of the sample, obtained with the use of a multivariate calibration model formed according to the given method, very slightly depend on the measurement conditions and the technical parameters of the measuring instrument. The intentional introduction of the results measurement data variability of the calibration samples set raises the model's stability, and the area of its applicability becomes wider.

The given method is not deprived of drawbacks. First, it is necessary to note the decrease in the analysis results accuracy with the similar calibration model use, what is conditioned by the initially prospective variation of primary properties measurement results. The same circumstance complicates the calibration applicability estimation for the analysis of this or that unknown sample. For example, if the calibration model for the determination of various chemical components percentage in the sample will be used for the analysis of an unknown sample, consisting of other components and substantially differing from the calibration set samples, it will lead to mistakes in the secondary properties determination. Besides, the construction of a mathematical model, insensitive to the effect of all factors, influencing the measurement results, is not always possible, owing to the great number of similar factors. Therefore, the process of the calibration model formation, accounting the effect of a big number of additional factors, demands carrying out of a huge volume of calibration samples measurements under various conditions, that fact increases even more the labor input and the duration of the calibration formation procedure.

The problem of the present invention is the formation of a multivariate calibration model, which provides a high accuracy of analyzed properties determination and is stable to the changes of properties, influencing the measurement results of the instrument, and even in case of the similar factors repeated change, in particular, to possible linear and nonlinear instrument's technical parameters differences, arising owing to ageing, performance of repair or replacement of separate typical elements of the design, change of operational conditions, and also other factors, any way, the labor input and the construction procedure duration of the similar model, subsequently applied for the determination of one or several secondary properties of the unknown sample by the results of the multiple primary properties measurement of this sample, and not necessarily spectral ones, decrease.

The solution of the problem put by is achieved with the help the of multivariate calibration models formation method, consisting of a sequence of actions united by a uniform inventor's plan. The method includes the calibration set samples selection with the known secondary properties, determined by reference methods; the instrumental measurement of each calibration set samples' primary properties; the artificial alteration, at least, in one of the properties, affecting the instrument measurement results; measurement of, at least, one sample on the instrument with the primary properties in the state, changed in this way; the formation of a calibration model, stable to the specified changes, by finding through multivariate regressive analysis methods with the use of the data, obtained on the instrument after the introduction of changes, the calibration relationships, allowing one to determine the analyzed secondary properties of the unknown sample by measurement results of the set of primary properties of this sample, which differ by the fact that before the change introduction they form a set of samples for calculation of correcting relationships, they measure the primary properties of each sample from this set on the instrument before and after the alteration, and, comparing by means of multivariate regressive analysis methods the measurement results of the primary properties of samples of the set, obtained on the instrument before alteration, with the measurement results of primary properties of the same samples, obtained on the instrument in the state when changes are made, they determine the correcting relationships; therefore, the correcting relationships, found for one instrument and considering the brought in changes, are used on any other instrument of the given type at a stable to the specified changes calibration model construction; they carry out a transformation of the measurement results of the calibration set samples' primary properties by means of the obtained correcting relationships to the form, corresponding to the measurements on the instrument after alterations, thus, corrected for the changed state of the instrument, they supplement with the primary properties measurement results of the calibration set samples the calibration samples' primary properties measurement results, obtained on the instrument before the alteration, moreover, the check of the multivariate calibration model formed on the population of the initial and corrected primary properties measurement results of the calibration set samples, are made, carrying out a validation procedure and using the quantitative parameters of calibration validation determined on the basis of it.

The determination of correcting relationships, based on the measurement of the representative set of samples, formed according to the given method, allows accounting nonlinear differences in the instrument characteristics, conditioned by the properties change influencing the measurement results, since several dependences of primary properties change are used for finding the measurement results transformation relationships. In addition, there is no necessity to spend a huge volume of calibration set samples measurements under various conditions, and it considerably reduces the labor input and the duration of the formation process of the calibration model, stable to changes of the factors influencing the instrument measurements results, according to the offered algorithm.

Changes are brought in such way, that it is possible to capture their possible range while the instrument is in service. Therefore, the constructed calibration model will be stable even to repeated changes of the properties influencing the analysis results if their influence has been accounted by the offered calibration correction at the stage of its formation. This fact also is an essential advantage of the given method.

All results of the calibration samples measurements including the results of the calibration set samples primary properties measurement, supplementing the calibration set, transformed to the form equivalent to the measurement results on the instrument, when changes are introduced into, at least, one property of those influencing the measurement results, are kept in the computer of the given calibrated instrument. This provides independence of the formed model from the measurements on the instrument in the initial state, and allows estimating the legitimacy of the calibration application for the analysis of an unknown sample on the instrument in the state, when one or several properties, influencing the measurement results, have changed, and also allows determination the outlier data by means of the outliers prediction statistics, what guarantees a high accuracy of the analyzed secondary properties determination.

For the analysis accuracy estimation of unknown samples' secondary properties under a calculated calibration model, its check (validation) is carried out at the final stage. The given procedure is carried out by comparison of the samples' secondary properties, determined by the given calibration on the basis of the instrument measurement results, with the direct secondary properties measurement results, obtained with the use of reference methods.

The use of the outlier prediction statistics and the elimination from the model of outlier calibration set samples before the definition of the calibration relationships increases the stability of the created calibration model. For the transformation of the measurement results and of the reference data to the optimal form, it is possible to use the procedure of normalization. It allows to minimize the determination error of the analyzed secondary properties and to account the measuring instrument technical features, as well as distinction of sample preparation and the investigated sample state. The procedure of normalization represents a choice of this or that method of mathematical preprocessing. The criterion of choice is accuracy of the samples' secondary properties analysis, which is provided by the instrument with calibration, at which formation the given kind of mathematical preprocessing was used. As the basic quantitative criteria quantitative parameters of calibration model validation procedure (for example, a standard error of validation) [1] are used.

The obtained correcting relationships, accounting a certain variant of properties changes, affecting the measurements results of the instrument, are offered to be used with the purpose of compensation of such changes at calibration construction and for any other instrument of the given type, using the declared algorithm.

The essence of the invention consists in the fact that the offered population of attributes allows forming on the calibrated measuring instrument a multivariate calibration model, stable to possible variations of properties affecting the instrument measurement results, in particular to the instrument technical parameters changes, arising owing to ageing, performance of repair or replacement of separate typical elements of the design, as well as to service conditions factors, moreover, even in case of numerous changes of the specified factors, in addition, the labor input and the construction procedure duration of the similar model in comparison with the existing known methods decreases. The created calibration model gives an opportunity with high accuracy to predict unknown samples' secondary properties by measurement results of the set of primary properties, not necessarily spectroscopic, moreover, the calibration model is constructed on the basis of the data on the primary properties from the calibration set samples, measured on the calibrated instrument, and the same data, transformed to the form as though the measurements were spent on the instrument, when some changes had been made, at least, in one of the properties, affecting the instrument measurement results, for example, corresponding maximal expected changes while in service for instruments of the given type. The correcting relationships, that allow transforming of the calibration samples measurement results to the form, equivalent to the instrument measurement results in the altered condition, are determined from the representative set of samples measurement on the instrument before and after the alteration, moreover, the set for the correcting relationships calculation consists of a much smaller quantity of samples, than the calibration one. Samples from the set for the correcting relationships calculation provide the essential distinctions in the measurement results in all primary properties range on the instrument, both in the initial, and in the altered state. The samples set use for calculation of correcting relationships allows defining the nonlinear connection between the measurement results of the same samples on the instrument before and after the alteration by the correlation analysis with the regressive methods use. The obtained correcting relationships, accounting a certain variant of changes, at least, of one factor, affecting the instrument measurement results, are offered to be used at calibration models construction with the purpose of compensation of such alterations and for any other instrument of the given type. Thus, there is an opportunity of calibration construction for any other instrument, stable to the calibrated instrument technical parameters differences, arising owing to ageing, performance of repair or replacement of separate typical elements of the design, to service conditions changes, as well as other properties, affecting the instrument's measurement results, using the correcting relationships, calculated only for one instrument on the basis of the offered algorithm, what in an even greater degree simplifies the process of calibration models formation. As at calibration models construction a population of the primary properties measurement results of the calibration set samples, obtained on the instrument in an initial state, and also reduced to the kind of the instrument, when, at least, one property measurement, affecting the results, is altered, it is possible to estimate the constructed calibration applicability legitimacy for the analysis of an unknown sample, using statistical methods of outlier data analysis, for example, on Mahalanobis distance. The normalization procedure performance with the use of various kinds of mathematical preprocessing results of measurements and the data on the secondary properties (reference data), allows providing the minimal error of analyzed secondary properties determination, having determined, thus, the optimal calibration relationships for the given conditions.

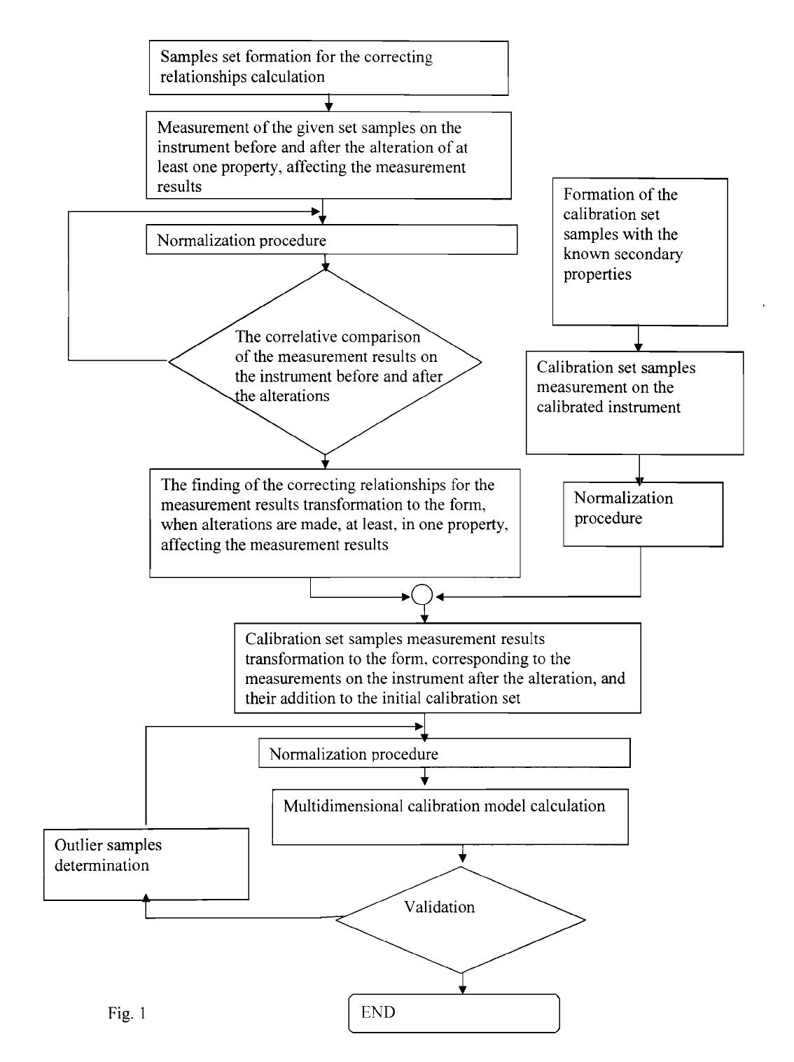

The declared invention is explained in FIG. 1, where the schematic image of the declared method in the form of a flow-oriented diagram is presented.

The declared method of multivariate calibration models formation can be used for any instruments, where the analyzed sample's properties are determined on the basis of the repeated measurement of other properties, in particular, in spectrophotometry for various kinds of spectrometers, measuring the light radiation absorption by the sample on the magnitude of various wavelengths. The data, describing such measurement result, is referred to as spectrum. We shall consider the declared method application on the example of spectrometers for the chemical composition analysis of a sample, having noticed, however, once again, that the scope of the declared method is not limited to spectroscopy.

The spectrometer, as any other analytical instrument, demands the preliminary calibration, determining the interrelation between the analyzed properties of the sample and the spectral characteristics. We shall note, that frequently the analyzed properties of the sample are not compared directly with the measurement results but with the spectral data, which have already subjected the normalization procedure (preliminary mathematical preprocessing). In this way, for example, smoothing of spectra, subtraction of a base line or differentiation can be carried out. The type of the preliminary mathematical processing is chosen proceeding from the maximal accuracy definition criterion of the analyzed secondary properties and minimizing the influence of the collateral factors, connected with parasitic dispersion and samples preparation features. The same mathematical preprocessing is applied to all calibration set samples spectra, after carrying out of normalization procedure, the transformed spectral data have strongly pronounced characteristic features even at minor alterations of the analyzed properties [6]. As the criteria for the estimation of the calibration models quality of various statistical characteristics, for example, of the standard error of calibration (SEC), a standard error of validation (SEV), and a standard error of cross-validation (SECV) [1] are used. The most widespread kind of mathematical preprocessing at the spectral analysis is the determination of the spectral data weight-average values [6], which reduces by one number the freedom degrees in the calibration model. In the given preprocessing, the averaged for all calibration set spectrum is found, and then subtract it from each calibration samples spectrum. Similarly, the weight-average values of the reference data are determined. Then, at the unknown sample analysis before the constructed calibration model application, the averaged for the calibration set spectrum is subtracted from the measured spectrum.

The set of samples, representative to those samples, which further on will be analyzed, is selected for carrying out calibration. While choosing the calibration samples for the spectral analysis, the following criteria [1] are used: a) samples should contain all chemical components, which it is planned to analyze; b) the range of change of the analyzed components concentration in the calibration set samples should exceed the range of change in the analyzed unknown samples; c) the amounts of alteration in the chemical components concentration from sample to sample should be distributed at regular intervals within all range of alterations; d) the number of samples should provide the determination by means of statistical methods of mathematical relationships between the spectroscopic data and the concentration of separate chemical components. The samples, dropping out from the calibration set, are determined by means of the outlier statistical analysis, for example, by calculation of Mahalanobis distance [1], which is defined as:

D²=r^{t}(R·R^{t})⁺r (1)

Where R—is the matrix of full calibration set spectral data, r—is a vector, corresponding to the spectrum of one sample. Mahalanobis distance shows, how many degrees of freedom the given sample brings into the calibration model. On the average, every calibration sample should bring in k/m, where k—is the number of variables in the regression, m—is the number of samples in the calibration set. Samples with D²>3 k/m should be excluded from the calibration set. A big value of Mahalanobis distance means that the spectrum of the given sample almost completely determines one of the regressive factors, what makes the model unstable. This can occur, when the uniformity of the analyzed calibration samples' properties distribution within the range, in which they change, is disturbed, i.e. when the composition of the sample essentially differs from other samples in the calibration set. Samples, which analyzed properties values, determined by means of the constructed model, considerably differ from the values, which are obtained by the reference method, should be excluded from the calibration set. The given samples are determined from the Student divergences, calculated by the formula:

$${t}_{i} = \frac{{e}_{i}}{SEC \sqrt{1 - {D}_{i}^{2}}} \qquad ( 2 )$$

Here eᵢ—is the difference obtained by means of a calibration model of the chemical component concentration value or the analyzed property from the reference value for i-^{th} calibration sample, SEC—is a standard error of calibration [1], Dᵢ²—is Mahalanobis distance for i-^{th} calibration sample. Student divergences should be distributed at regular intervals under the normal law. The amount of divergence is compared with the Student factor, for the confidence probability 0.95 and the numbers of degrees of freedom m-k. In case if the amount of the divergence exceeds the factor, the sample is excluded from the calibration set.

The analyzed calibration samples properties should be known in advance or are to be determined by means of reference methods. The obtained numerical values are considered the real values of the analyzed properties, therefore the reference analysis accuracy determines the accuracy of all calibration, and rather big demands are made to this procedure. It is possible to increase the reference analysis accuracy, conducting a repeated recurrence of analyses with the subsequent averaging of the results.

The calibration samples set spectra are registered on the instrument, and then a multivariate calibration model can be formed. For these purpose multivariate mathematical methods, such as, the principal components analysis (PCA), the partial least squares procedure (PLS), etc. Further, when measuring the unknown sample's spectrum on the given instrument and using the created calibration model, it is possible to determine the analyzed properties, for example, the chemical composition. The accuracy of similar measurements will be high enough until the properties, affecting the measurement results of the instrument, remain constant. However, as it was already mentioned earlier, while, for example, in service, at carrying out of repair work or replacements of separate typical elements of the design, characteristics of the instrument can change, what in its turn can lead to the decrease in predictions accuracy and to the necessity of a new calibration model construction. Hence, for the sufficient accuracy maintenance of the unknown samples properties prediction on the instrument under the condition of possible repeated alterations of factors, affecting the measurement results, it is necessary to have a calibration model, stable to distinctions in the instrument characteristics, to changes of operation conditions and to other properties, affecting the measurement results of the instrument, in addition providing the prescribed accuracy of the analysis, allowing to estimate the model applicability for the analysis of the unknown sample, moreover the process of the similar calibration formation should not be excessively long and labor-consuming.

The declared method allows forming a multivariate calibration model for the calibrated instrument, stable to possible changes of one or several factors affecting its measurement results, permits not to conduct a full calibration samples set measurement on the instrument, when the specified factor or factors have changed, moreover it is true even in case of repeated changes. For the calibration formation the spectral data, measured on the calibrated instrument, supplemented with the spectral data obtained as a result of the initial data transformation to the form, equivalent to measurements on the instruments in the state, when at least one of the properties, affecting the measurement results, is changed, for example, in such way that it comprises the expected range of similar changes for instruments of the given type while in service. The area of the calibration model applicability and stability is analyzed on the basis of these spectral data population. As all data are kept in the calibrated instrument computer, it allows estimating the outlier data at the analysis of unknown samples, for example, by means of Mahalanobis statistics.

For the calibration set spectral data correction, carried out with the purpose of the account of the properties changes, affecting the measurement results of the instrument, a specially selected samples set further called a set for correcting relationships calculation is used, the number of samples in which is much less, than in a full calibration set, thus their properties can be unknown, it is only important that this set of samples provides significant variations in the measured spectral data, allowing to determine the transformation expressions. For this purpose the spectrum of each sample of the set is measured on the instrument in the state, corresponding to the samples calibration spectra measurement, and on the same instrument, when at least in one of the properties, influencing the measurement results, some changes are introduced (the “changed” instrument). While realizing the obtained spectral data correlation, they find the relationships, allowing to transform the spectra measured on the instrument before the alteration, to the form as though the measurements were made on the changed instrument, and accounting the distinctions in the measurement results of the same samples, arising owing to the alteration of one or several factors, affecting the measurement results of the instrument. With the purpose of the optimum calibration, the spectral data can be exposed to normalization, which consists in carrying out of identical mathematical transformations for all measured spectra. It provides the revealing of obvious differences in the spectral data, measured on the instrument before and after the alteration, what, in its turn, facilitate a more exact expressions definition for the spectral data transformation. It should be noted, that the correcting relationships, found in a similar way for any instrument, accounting the affect of alterations of a certain property or properties on the measurement results of the instrument, could be used on any other instrument of the given type at the construction of the calibration model, stable against the specified alterations. The listed attributes population allows lowering the labor input and the duration of the formation process of the calibration model, stable against alterations of the properties, affecting the measurement results of the instrument. The calibration model for the calibrated instrument is formed by the initial and transformed spectral data of the given calibration samples set, using standard mathematical methods of the multivariate regressive analysis (MLR, PCA, PLS, etc. [6]), in addition, the outlier samples should be excluded from calibration, what guarantees the formed model stability, then, it can be used for the determination of the unknown sample properties.

As a practical explanation of the declared invention we shall consider an example of a multivariate calibration model formation, stable against the technical parameters alterations of spectrometer InfraLUM FT-10, which can occur owing to ageing, performance of repair or replacement of separate typical elements of the design. The principle of the given instrument operation is based on Fourier spectroscopy in the near infrared spectral region (NIR). Bread-wheat was chosen as the research object, for which by means of the constructed calibration on the given instrument the basic quality parameters were determined. We shall emphasize in addition that the given example is only used as a practical illustration of the offered method.

For the formation of the calibration, a representative samples set, spectra of which are measured on the spectrometer, is selected. The obtained spectral data can be exposed to the normalization procedure, with due account for the features of instruments, operating in transmission mode and using the principles of Fourier spectroscopy [6]. At the calibration models construction within the limits of the given research the following preprocessing was used: the alignment of the baseline, the spectra normalization by a root-mean-square deviation, calculation of the weighted average values [6].

As it was mentioned earlier, the type of the mathematical processing is defined in such way that it provides the minimal error of the analyzed properties determination. If the spectral data are exposed to the normalization procedure, the calibration relationships are determined on the basis of these data comparison with the known, which also passed normalization, properties of the calibration set samples, determined by reference methods.

For the assessment of the formed calibration model quality various statistical characteristics are used [1].

One of such parameters is a standard error of calibration (SEC), which serves for the assessment of the expected agreement between the obtained values, using the calibration model, and the values measured by the reference method.

$$SEC = \sqrt{\frac{{\sum }_{i = 1}^{n} {( {{y}^{⋒}}_{i} - {y}_{i} )}^{2}}{d}} \qquad ( 3 )$$

Where y̅—is a vector of values of the desired parameters predicted by the calibration model for calibration set of samples; y—is a vector of reference data; d=n−k—is the number of degrees of freedom in the calibration model, n—is the number of calibration samples, k—is the number of variables in the calibration model, depending on the mathematical method, used for the model construction.

The standard error of cross-validation (SECV) is calculated at a cross check of the calibration model and allows assessing its stability [1].

$$SECV = \sqrt{\frac{{\sum }_{i = 1}^{n} {( {{y}^{⋒}}_{i} - {y}_{i} )}^{2}}{n}} \qquad ( 4 )$$

Where ŷ—is the containing cross-validation estimates vector.

The standard error of validation (SEV) characterizes the deviation error between the reference and the predicted by the calibration equation values for the samples of the additional set of samples not included in the calibration one.

$$SEV = \sqrt{\frac{{\sum }_{i = 1}^{n} {( {{y}^{⋒}}_{i} - {y}_{i} )}^{2}}{{d}_{v}}} \qquad ( 5 )$$

Where dᵥ—is the total number of reference values of the analyzed parameter for all spectra of the additional set, yᵢ—are the reference values of the analyzed parameter for i-^{th} spectrum of the additional set, and yᵢ—are the predicted values of the analyzed parameter for i-^{th} spectrum of the additional set.

The basic statistical characteristics of the initial calibration model, formed by the samples of bread-wheat on the investigated spectrometer without an artificial alteration in the properties, affecting the measurement results, are given in table 1. Calibrations have been constructed on two basic quality parameters—protein and gluten. For the determination of SEV a validation set was used, it was chosen in such way that the contents in it of accordingly protein or gluten was distributed at regular intervals within all range of possible values of these parameters concentration.

TABLE 1
Results of the initial instrument calibration.

| Parameter | SEC | SECV | SEV |
|---|---|---|---|
| Protein | 0.32 | 0.41 | 0.31 |
| Gluten | 1.24 | 1.51 | 1.14 |

To create on the spectrometer a multivariate calibration model, accounting possible properties alterations, affecting the measurement results of the instrument, for example, differences in technical parameters of the instrument, arising owing to ageing, performance of repair or replacement of separate typical elements of the design, it is necessary to generate according to the declared invention a set of samples for calculation of the correcting relationships between the results, obtained on the instrument in the initial state, and in the state, when alterations are made. In this case, 10 samples were selected from the calibration set with the maximal and minimal values of score parameter for each of the analyzed parameters. However, we shall note, that the samples in the set for calculation of the correcting relationships generally may not belong to the calibration set.

The chosen samples spectra were registered on the calibrated instrument. Then some artificial changes were made in the design features of the given instrument, for example those, which are possible at analyzer repair. In particular, in the given example the replacement of a beam splitter in the interferometer for another one, the covering of which differs from the initial so much, that it causes the greatest possible deviations in the light beam distribution among the beam splitters of the given class. After that the measurements of samples for correcting relationships calculation on the instrument, changed in this way, were carried out, and, by correlation of the spectral data, obtained on the instrument before and after the alteration, the expressions for transformation of the measurement results on the instrument in the initial state to the form, corresponding to the measurements on the instrument after the alteration, were found. In the elementary form, these relationships can be defined by the linear regression method.

R_{i,j}^{s}=a′ᵢ+a″ᵢR_{i,j}^{m} (6)

Where R_{i,j}^{s}—are the spectral data values measured on the instrument, when changes were made in its design (i-^{th} wavelength, j-^{th} sample from the set for correcting relationships calculation), and R_{i,j}^{m}—are the similar spectral data measured on the instrument before the alteration. The spectral data can be exposed to the procedure of normalization; in addition, the used mathematical processing should be identical for the spectra measured on the instrument both before, and after the alteration. The regression factors are found for the correcting relationships determination by the method of the least squares.

$${a}_{i}^{′} = ( \begin{matrix}{\sum }_{j = 1}^{c} {R}_{i , j}^{{m}^{2}} * {\sum }_{j = 1}^{c} {R}_{i , j}^{s} - \\ {\sum }_{j = 1}^{c} {R}_{i , j}^{m} * {R}_{i , j}^{s} * {\sum }_{j = 1}^{c} {R}_{i , j}^{m}\end{matrix} ) / ( c * {\sum }_{j = 1}^{c} {R}_{i , j}^{{m}^{2}} - {( {\sum }_{j = 1}^{c} {R}_{i , j}^{m} )}^{2} ) \\ {a}_{i}^{″} = ( \begin{matrix}c * {\sum }_{j = 1}^{c} {R}_{i , j}^{m} * {R}_{i , j}^{s} - \\ {\sum }_{j = 1}^{c} {R}_{i , j}^{m} * {\sum }_{j = 1}^{c} {R}_{i , j}^{s}\end{matrix} ) / ( c * {\sum }_{j = 1}^{c} {R}_{i , j}^{{m}^{2}} - {( {\sum }_{j = 1}^{c} {R}_{i , j}^{m} )}^{2} ) \qquad ( 7 )$$

Where c—is the quantity of samples in the set for correcting relationships calculation.

After finding the correcting relationships, using the determined regression factors a′ᵢ and a″ᵢ the spectral data for each sample from the calibration set according to the formula (6) are transformed to the form corresponding to the measurements on the instrument after the alteration. Further a new multivariate calibration model is formed by the population of the initial and transformed data, which is checked by means of the standard validation procedure [1] therefore its basic statistical parameters are determined.

For the check of the offered method efficiency, various beam splitters were installed on the investigated instrument, and in each case, the validation samples set spectra were registered. After that, on the basis of the standard validation procedure [1], the basic statistical parameters of the initial and corrected calibration models were assessed. In table 2 the data for the initial calibration are given, and in table 3 for the corrected, stable against the influence of a beam splitter replacement, are cited.

From the given data it is seen, that the multivariate calibration model, formed according to the declared invention, allows determination the properties of unknown samples with high accuracy and, in addition, it is much less sensitive to the possible change of the instrument design accounted by means of the offered algorithm, in this case the replacement of the beam splitter. Any other changes of properties, affecting the measurements results of the instrument, can be accounted in a similar way, the example, shown here, is chosen as an evident illustration of the declared invention because similar changes are the most typical for spectrometers of the given type, and are capable to lead to a significant decrease in the accuracy of the analysis on the initially constructed calibration model of the instrument if they are not accounted at its formation.

TABLE 2
Check of the initial calibration on the
instrument with various beam splitters.

| | | Number of beam splitter | | | | | |
|---|---|---|---|---|---|---|---|
| | Number of | Ref. | | | | | |
| Component | sample | values | Initial | 1 | 2 | 3 | 4 |
| Protein | 4105 | 13.00 | 12.66 | 13.63 | 13.15 | 13.71 | 13.72 |
| | 4122 | 13.53 | 13.64 | 13.51 | 13.79 | 13.59 | 13.47 |
| | 4126 | 12.20 | 12.36 | 12.37 | 12.47 | 12.44 | 12.09 |
| | 4146 | 11.40 | 11.46 | 11.35 | 11.46 | 11.46 | 11.31 |
| | 4369 | 11.70 | 11.68 | 11.60 | 11.25 | 11.81 | 11.89 |
| | 4376 | 13.60 | 13.46 | 13.27 | 13.63 | 13.65 | 13.55 |
| | 4379 | 13.30 | 13.39 | 13.38 | 13.26 | 13.15 | 13.15 |
| | 4387 | 12.30 | 12.27 | 12.31 | 12.03 | 12.26 | 12.32 |
| | 4388 | 12.20 | 12.25 | 12.14 | 12.26 | 12.26 | 12.39 |
| | 4648 | 14.05 | 13.87 | 14.03 | 14.13 | 14.10 | 14.47 |
| | 4666 | 10.58 | 10.49 | 10.51 | 11.37 | 11.02 | 11.83 |
| | SEV | | 0.31 | 0.38 | 0.63 | 0.41 | 0.61 |
| Gluten | 4122 | 25.00 | 24.76 | 24.19 | 24.34 | 25.14 | 25.26 |
| | 4146 | 17.80 | 17.23 | 17.91 | 17.40 | 17.25 | 18.08 |
| | 4369 | 15.10 | 16.10 | 15.55 | 16.17 | 17.40 | 18.50 |
| | 4371 | 23.00 | 22.00 | 22.59 | 19.76 | 21.18 | 23.51 |
| | 4376 | 22.40 | 22.31 | 21.82 | 21.17 | 21.31 | 22.18 |
| | 4387 | 18.70 | 17.88 | 18.11 | 18.56 | 18.88 | 18.57 |
| | 4629 | 17.44 | 17.44 | 16.83 | 18.65 | 17.22 | 18.02 |
| | 4648 | 22.00 | 21.75 | 21.21 | 20.54 | 23.58 | 25.12 |
| | SEV | | 1.14 | 1.19 | 2.33 | 1.67 | 2.15 |

TABLE 3
Check of the calibration, corrected in view of the beam splitter
replacement, on the instrument with various beam splitters.

| | | Number of beam splitter | | | | | |
|---|---|---|---|---|---|---|---|
| | Number of | Ref. | | | | | |
| Component | sample | values | Initial | 1 | 2 | 3 | 4 |
| Protein | 4105 | 13.00 | 13.30 | 13.39 | 13.25 | 13.41 | 13.38 |
| | 4122 | 13.53 | 13.64 | 13.54 | 13.62 | 13.64 | 13.69 |
| | 4126 | 12.20 | 12.40 | 12.46 | 12.38 | 12.28 | 12.05 |
| | 4146 | 11.40 | 11.45 | 11.44 | 11.37 | 11.33 | 11.28 |
| | 4369 | 11.70 | 11.65 | 11.49 | 11.48 | 11.58 | 11.77 |
| | 4376 | 13.60 | 13.45 | 13.25 | 13.68 | 13.58 | 13.54 |
| | 4379 | 13.30 | 13.37 | 13.36 | 13.29 | 13.11 | 13.10 |
| | 4387 | 12.30 | 12.25 | 12.27 | 12.19 | 12.27 | 12.36 |
| | 4388 | 12.20 | 12.22 | 12.20 | 12.29 | 12.20 | 12.34 |
| | 4648 | 14.05 | 13.90 | 14.19 | 13.98 | 13.99 | 14.22 |
| | 4666 | 10.58 | 10.44 | 10.44 | 11.16 | 11.09 | 11.13 |
| | SEV | | 0.28 | 0.34 | 0.38 | 0.33 | 0.37 |
| Gluten | 4122 | 25.00 | 24.65 | 24.25 | 24.29 | 25.19 | 25.00 |
| | 4146 | 17.80 | 17.03 | 17.59 | 18.12 | 17.02 | 17.53 |
| | 4369 | 15.10 | 16.38 | 15.72 | 16.00 | 16.58 | 16.99 |
| | 4371 | 23.00 | 21.90 | 22.57 | 21.62 | 21.51 | 24.11 |
| | 4376 | 22.40 | 22.17 | 21.48 | 21.32 | 21.37 | 22.64 |
| | 4387 | 18.70 | 18.22 | 18.27 | 19.10 | 18.78 | 18.55 |
| | 4629 | 17.44 | 17.26 | 17.18 | 16.66 | 17.88 | 17.25 |
| | 4648 | 22.00 | 22.07 | 21.81 | 21.43 | 22.61 | 23.41 |
| | SEV | | 1.08 | 1.12 | 1.46 | 1.38 | 1.52 |

The check of the opportunity to use the found correcting relationships on another instrument of the same model has been made. On this instrument the spectra of the samples calibration set of bread-wheat, chosen for this instrument, were registered, and on the basis of the data a calibration model is constructed, this model does not account the possible properties change affecting the measurement results of the instrument.

After that, the spectral data, obtained at measurement on the graduated instrument of the calibration set of samples, have been corrected by the correcting relationships found earlier to the form corresponding to the instrument, for which the replacement of a beam splitter is carried out. According to the offered algorithm, the calibration model was formed by the set of the initial and corrected spectral data of the calibration samples of the instrument.

For the check of the offered method efficiency on the calibrated instrument, various beam splitters were installed, and in each case, the spectra of the samples validation set were registered. After that on the basis of the standard validation procedure [1] the initial calibration model basic statistical parameters, formed for the given instrument, and the calibration models, stable against beam splitter replacement affect, on the basis of the correcting relationships, calculated earlier for another instrument, were assessed. The obtained data are shown accordingly in tables 4 and 5.

TABLE 4
Calibration check of the second instrument on
the instrument with different beam splitters.

| | | Number of beam splitter | | | | | |
|---|---|---|---|---|---|---|---|
| | Number of | Ref. | | | | | |
| Component | sample | values | Initial | 1 | 2 | 3 | 4 |
| Protein | 4105 | 13.00 | 13.02 | 12.80 | 12.61 | 12.73 | 13.18 |
| | 4116 | 15.70 | 15.34 | 15.21 | 15.05 | 15.27 | 15.23 |
| | 4118 | 14.00 | 14.05 | 13.88 | 13.70 | 13.96 | 14.03 |
| | 4122 | 13 53 | 13.59 | 13.54 | 13.67 | 13.45 | 13.37 |
| | 4126 | 12.20 | 12.31 | 12.44 | 12.22 | 12.26 | 12.24 |
| | 4146 | 11.40 | 11.12 | 11.40 | 11.46 | 11.42 | 11.18 |
| | 4172 | 13.20 | 13.30 | 13.31 | 13.09 | 13.17 | 13.09 |
| | SEV | | 0.28 | 0.37 | 0.41 | 0.38 | 0.37 |
| Gluten | 4105 | 19.80 | 20.68 | 21.44 | 20.80 | 21.29 | 21.02 |
| | 4116 | 24.20 | 24.71 | 25.06 | 24.83 | 24.15 | 24.40 |
| | 4118 | 23.32 | 23.44 | 23.56 | 23.66 | 22.95 | 23.78 |
| | 4122 | 25.00 | 25.16 | 25.15 | 24.95 | 25.28 | 25.21 |
| | 4126 | 16.60 | 16.75 | 17.08 | 17.10 | 17.11 | 16.93 |
| | 4146 | 17.80 | 16.71 | 17.90 | 17.36 | 17.35 | 17.00 |
| | 4172 | 20.50 | 20.56 | 20.55 | 20.84 | 20.51 | 20.18 |
| | SEV | | 0.96 | 1.19 | 1.03 | 0.93 | 1.01 |

TABLE 5
Check of the calibration corrected in view of the beam splitter replacement
by the correcting relationships, determined for another instrument,
on the graduated instrument with various beam splitters.

| | | Number of beam splitter | | | | | |
|---|---|---|---|---|---|---|---|
| | Number of | Ref. | | | | | |
| Component | sample | values | Initial | 1 | 2 | 3 | 4 |
| Protein | 4105 | 13.00 | 13.04 | 12.91 | 12.78 | 12.86 | 12.95 |
| | 4116 | 15.70 | 15.47 | 15.38 | 15.20 | 15.42 | 15.54 |
| | 4118 | 14.00 | 14.04 | 14.05 | 13.84 | 13.90 | 14.00 |
| | 4122 | 13.53 | 13.72 | 13.58 | 13.36 | 13.49 | 13.60 |
| | 4126 | 12.20 | 12.08 | 12.16 | 12.16 | 12.06 | 12.39 |
| | 4146 | 11.40 | 11.01 | 11.25 | 11.25 | 11.45 | 11.38 |
| | 4172 | 13.20 | 13.30 | 13.31 | 13.13 | 13.20 | 13.33 |
| | SEV | | 0.27 | 0.30 | 0.32 | 0.31 | 0.30 |
| Gluten | 4105 | 19.80 | 19.97 | 20.83 | 20.16 | 20.77 | 21.04 |
| | 4116 | 24.20 | 24.64 | 24.85 | 24.70 | 23.98 | 24.29 |
| | 4118 | 23.32 | 23.43 | 23.30 | 23.83 | 22.93 | 22.99 |
| | 4122 | 25.00 | 24.93 | 25.15 | 24.84 | 25.39 | 25.31 |
| | 4126 | 16.60 | 16.81 | 17.48 | 17.23 | 17.25 | 17.29 |
| | 4146 | 17.80 | 16.65 | 17.78 | 17.57 | 17.17 | 17.22 |
| | 4172 | 20.50 | 20.48 | 20.41 | 20.99 | 20.96 | 20.72 |
| | SEV | | 0.94 | 1.06 | 0.92 | 0.86 | 0.93 |

The results of tables 4 and 5 confirm the opportunity to use the correcting relationships determined for any instrument and considering the effect of its parameters or other properties changes, affecting the measurement results, on any other instrument of the given series at formation of a stable against the specified changes calibration models. The given feature allows, after the formation according to the offered method of a calibration model, compensating differences, affecting the measurement results of a certain property or properties, for example, of technical parameters of the instrument, which changes occur owing to ageing, performance of repair or replacement of separate typical elements of the design, for an instrument, further, it is possible to use the found correcting relationships for all other instruments of the given type at calibration models construction, accounting by means of the given correction relationships the respective alterations of the influencing properties. In that case there is no necessity to choose and carry out samples set measurements for calculation of correcting relationships for all other instruments, except for the first, as the spectral data, obtained at calibration samples registration on other instruments, will be mathematically transformed with the use of the found correcting relationships to the form, corresponding to the instrument, when some changes are made to one or several properties affecting the measurement results.

In the conclusion once again we shall note, that the scope of the declared method is not limited by spectroscopy. The declared invention can be used for the various devices, determining some properties of the sample on the basis of the repeated measurement of other properties.

### CHANNELS OF INFORMATION

1. ASTM standard, E 1655-00, Practices for Infrared Multivariate Quantitative Analysis.
2. U.S. Pat. No. 4,944,589, IPC G01J 3/18, published on 31 Jul. 1990
3. U.S. Pat. No. 6,615,151, IPC G01N 015/06, published on 2 Sep. 2003
4. European patent application EP 0 225 233, IPC G01N 021/27E published on 28 Mar. 2002
5. Russian patent application N^{o} 2266523 C1, IPC 7: G01N 021/01, published on 20 Dec. 2005
6. Operation manual InfraLUM FT-10, 152.00.00.00.0M.

1. The method of formation of the multivariate calibration models, stable against properties changes, affecting the measurement results of the device, including the selection of the samples calibration set with the known secondary properties; the measurement on the device of the primary properties of each samples calibration set; artificial alteration, at least, in one of the properties, affecting the measurement results of the device; measurement of the primary properties, at least, in one sample on the device in the thus changed state, differing with the fact that before the alteration a set of samples for calculation of correcting relationships is formed, the primary properties of each sample from this set are measured on the device before and after the alterations, and, comparing, by means of the multivariate regressive analysis methods, the measurement results of the primary properties of the samples of the set, obtained on the instrument before the alterations, with the measurement results of the primary properties of the same samples, obtained on the device in the state, when changes are made, determine the correcting relationships; carry out transformation of the measurement results of the calibration set samples' primary properties by means of the obtained correcting relationships to the form, corresponding to the measurements on the device after the alteration; the corrected in such way to the changed state of the device with primary properties measurement results of the calibration set samples, are supplemented with the measurement results of the calibration samples primary properties, obtained on the device before the alteration, the multivariate calibration model is calculated by the population of the initial and corrected measurement results of the primary properties of the calibration set samples, and its check, determining on the basis of it the quantitative parameters of the calibration validation, is made.

2. The method under item 1, distinguished by the fact that, carrying out comparison by means of methods of the multivariate regressive analysis of the measurement results of the set samples' primary properties for the calculation of the correcting relationships, obtained on the device before the alteration, with the measurement results of the same samples primary properties, obtained on the device in the state, when changes are made, the measurement results of the specified samples on the device both before, and after the alteration, are preliminary exposed to the normalization procedure, revealing the differences in the measurement results of the set samples for the calculation of the correcting relationships, depending on the alterations, moreover, carrying out the measurement results of the calibration set samples primary properties transformation by means of the obtained correcting relationships to the form, corresponding to measurements on the device after the alteration, the calibration set samples measurement results are preliminarily exposed to the precisely same procedure of normalization on the device before the alteration.

3. The method under item 1, distinguished by the fact that samples, describing the existing range of differences in the primary properties measurement results on the calibrated instrument both before, and after the alteration, are selected for the set for correcting relationships calculation.

4. The method under item 1, distinguished by the fact that samples of the correcting relationships calculation, which properties characterize the existing range of the samples' secondary properties changes, are selected for the set.

5. The method under item 1, distinguished by the fact, that if at carrying out of check of the multivariate calibration model, formed by the set of initial and corrected results of the calibration set samples primary properties measurement, the found quantitative parameters of calibration validation mismatch the set accuracy criteria, the population of the initial and corrected measurement results of the of calibration set samples' primary properties is analyzed for the presence of outlier data by means of the outliers prediction statistics, and before the determination of the calibration relationships exclude the outlier samples from the calibration set.

6. The method under item 1, distinguished by the fact, that if at carrying out of check of the multivariate calibration model, formed by the set of initial and corrected results of the calibration set samples' primary properties measurement, the found quantitative calibration validation parameters mismatch the prescribed accuracy criteria, the population of the initial and corrected calibration set samples' primary properties measurement results and (or) the corresponding known secondary properties of the calibration samples are exposed to the procedure of normalization.

7. The method under item 1, distinguished by the fact, that the formed multivariate calibration model provides a linear interrelation between the primary and the secondary properties.

8. The method under item 1, distinguished by the fact that the formed multivariate calibration model provides a non-linear interrelation between the primary and the secondary properties.

9. The method under item 1, distinguished by the fact that a calibrated instrument is used as a spectrometer, moreover, the samples' spectral characteristics measurement results, describing the absorption, reflection or dispersion of light at different values of wave numbers, are the primary properties.
